(19) United States
(12) Patent Application Publication
(10) Pub. No.: US 2012/0160310 A1
(43) Pub. Date: Jun. 28, 2012

(54) Manufacturing Method of Thin Film Solar Cells and Thin Film Solar Cells Thereof

(75) Inventors: Chen-Wei Peng, Miaoli City (TW); Chun-Hsiung Lu, Hsinchu City (TW); Chao-Hsiung Huang, New Taipei City (TW); Ping-Kuan Chang, Tainan City (TW)

(73) Assignee: NEXPOWER TECHNOLOGY CORPORATION, Taichung City (TW)

(21) Appl. No.: 13/331,490

(22) Filed: Dec. 20, 2011

(30) Foreign Application Priority Data
Dec. 27, 2010 (TW) 099146191

(51) Int. Cl. H01L 31/06; H01L 31/18

(52) U.S. Cl. 136/255; 438/73; 257/E31.001

(57) ABSTRACT

A manufacturing method of thin film solar cells and thin film solar cells thereof. The thin film solar cells comprise a substrate, an amorphous silicon layer, a first conductive layer, a stacked I-layer, a second conductive layer and a back contact layer. The amorphous silicon layer is on the substrate. The first conductive layer is on the amorphous silicon layer. The stacked I-layer is on the first conductive layer; the stacked I-layer from bottom to top is sequentially stacked by three different deposition rate I-layers: a first I-layer, a second I-layer and a third I-layer. Compared with the first and the third I-layer, the second I-layer has deposition rate higher than those of the other two I-layers. The second conductive layer is on the stacked I-layer. The back contact layer is on the second conductive layer for getting electric energy.

### CROSS-REFERENCE TO RELATED APPLICATION

This application claims the benefit of priority to Taiwan Patent Application No. 099146191, filed on Dec. 27, 2010, in the Taiwan Intellectual Property Office, the disclosure of which is incorporated herein in its entirety by reference.

### BACKGROUND OF THE INVENTION

1. Field of the Invention

The present invention relates to a manufacturing method of thin film solar cells and thin film solar cells thereof, in particular to the manufacturing method of the thin film solar cells by stacking intrinsic layers of the thin film solar cells to improve the mass production speed and the electric power efficiency of the thin film solar cells.

2. Description of the Related Art

Due to the world's energy shortage, different countries continue the research and development on alternative energy sources, and the solar cell used for solar generation catches the most attention, and the solar cell having the advantages of convenient use, inexhaustible supply, disposable free, pollution free, moving parts free, noise free, heat radiation insulation, long lifespan, variable size, combinable with buildings and easily accessible becomes a good alternate energy source.

In the 1970s, Bell Lab. developed the first silicon solar cell. Thereafter a variety of solar cells were developed. Till now, solar cells are used more extensively, and the solar cells are mainly divided into monocrystalline silicon solar cells, polycrystalline silicon solar cells, amorphous silicon solar cells, compound solar cells, and dye-sensitized solar cells, etc.

Silicon is a representative raw material used for manufacturing solar cells, and divided into: (1) monocrystalline silicon, (2) polycrystalline silicon, and (3) amorphous silicon. At present, the most-developed manufacturing technology and the largest market share are primarily based on the monocrystalline and amorphous silicon photovoltaic panels. Since (1) the monocrystalline silicon solar cell has the highest efficiency, (2) the amorphous silicon solar cell has the lowest price and the advantage of a quick manufacture without requiring any packaging process, and (3) the polycrystalline silicon solar cell requires more difficult cutting and downstream remanufacturing processes than the monocrystalline and polycrystalline silicon solar cells. In order to lower costs, the amorphous silicon thin film solar cells are developed positively, but the efficiency of the amorphous silicon thin film solar cells is still too low in practical applications. In recent years, the general thin film solar cell adopts a P-I-N structure to maintain a voltage output and allow an intermediate energy band to be situated in an area of an intrinsic layer (I-layer). Among a variety of thin film solar cells, a so-called microcrystalline Si (μc-Si: H) catches the most attention. The microcrystalline Si thin film generally has a carrier mobility with one or two levels higher than those of the amorphous silicon thin film, and a dark conductivity falling within a range from 10⁻⁵ to 10⁻⁷ (S/cm) and approximately 3 to 4 levels higher than that of the amorphous silicon thin film. However, the thin film solar cell with the conventional P-I-N structure still has an unsatisfactory mass production speed and a low electric power output efficiency.

Therefore, it is necessary to provide a manufacturing method of thin film solar cells and thin film solar cells, wherein different stacked P-I-N structures are adopted to improve the mass production speed and the photoelectric conversion efficiency of the solar cells.

### SUMMARY OF THE INVENTION

In view of the problems of the prior art, it is a primary objective of the present invention to provide a manufacturing method of thin film solar cells and thin film solar cells to overcome the problems of the low mass production speed and unsatisfactory photoelectric conversion efficiency.

To achieve the aforementioned objective, the present invention provides a thin film solar cell, comprising a substrate, an amorphous silicon layer, a first conductive layer, a stacked I-layer, a second conductive layer and a back contact layer. The amorphous silicon layer is disposed on the substrate. The first conductive layer is disposed on the amorphous silicon layer. The stacked I-layer is disposed on the first conductive layer and formed by stacking a first I-layer, a second I-layer and a third I-layer of different deposition rates sequentially from the bottom up. The second I-layer has a deposition rate higher than those of the first I-layer and the third I-layer. The second conductive layer is disposed on the stacked I-layer. The back contact layer is disposed on the second conductive layer for getting electric energy.

To achieve the aforementioned objective, the present invention further provides a manufacturing method of thin film solar cells, comprising the steps of: preparing a substrate; forming an amorphous silicon layer on the substrate; forming a first conductive layer on the amorphous silicon layer; forming a stacked I-layer on the first conductive layer by stacking a first I-layer, a second I-layer and a third I-layer of different deposition rates sequentially from the bottom up, and the second I-layer having a deposition rate higher than those of the first I-layer and the third I-layer; forming a second conductive layer on the stacked I-layer; and forming a back contact layer on the second conductive layer for getting electric energy.

To achieve the aforementioned objective, the present invention further provides a thin film solar cell, comprising a substrate, an amorphous silicon layer, a first conductive layer, a stacked I-layer, a second conductive layer and a back contact layer. The amorphous silicon layer is disposed on the substrate. The first conductive layer is disposed on the amorphous silicon layer. The stacked I-layer is disposed on the first conductive layer and formed by stacking a first I-layer and a second I-layer of different deposition rates sequentially from the bottom up, and the second I-layer has a deposition rate higher than that of the first I-layer. The second conductive layer is disposed on the stacked I-layer. The back contact layer is disposed on the second conductive layer for getting electric energy.

To achieve the aforementioned objective, the present invention further provides a manufacturing method of thin film solar cells, comprising the steps of: preparing a substrate; forming an amorphous silicon layer on the substrate; forming a first conductive layer on the amorphous silicon layer; forming a stacked I-layer on the first conductive layer by stacking a first I-layer and a second I-layer of different deposition rates sequentially from the bottom up, and the second I-layer having a deposition rate higher than that of the first I-layer; forming a second conductive layer on the stacked I-layer; and forming a back contact layer on the second conductive layer for getting electric energy.

To achieve the aforementioned objective, the present invention further provides a thin film solar cell, comprising a substrate, an amorphous silicon layer, a first conductive layer, a stacked I-layer, a second conductive layer and a back contact layer. The amorphous silicon layer is disposed on the substrate. The first conductive layer is disposed on the amorphous silicon layer. The stacked I-layer is disposed on the first conductive layer and formed by stacking a first I-layer and a second I-layer of different deposition rates sequentially from the bottom up, and the first I-layer has a deposition rate higher than that of the second I-layer. The second conductive layer is disposed at the stacked I-layer. The back contact layer is disposed on the second conductive layer for getting electric energy.

To achieve the aforementioned objective, the present invention further provides a manufacturing method of thin film solar cells, comprising the steps of: preparing a substrate; forming an amorphous silicon layer on the substrate; forming a first conductive layer on the amorphous silicon layer; forming a stacked I-layer on the first conductive layer, and the stacked I-layer being formed by stacking a first I-layer and a second I-layer of different deposition rates sequentially from the bottom up, and the first I-layer having a deposition rate higher than that of the second I-layer; forming a second conductive layer on the stacked I-layer; and forming a back contact layer on the second conductive layer for getting electric energy.

Wherein, the first conductive layer, the stacked I-layer and the second conductive layer are respectively a P-type semiconductor layer, an intrinsic semiconductor stacked layer, and an N-type semiconductor layer.

Wherein, the first I-layer is a positive orientation semiconductor I-layer.

In summation, the manufacturing method of thin film solar cells and the thin film solar cells of the present invention have the following advantage:

The manufacturing method of thin film solar cells and the thin film solar cells includes different stacked I-layers, together with a substrate, an amorphous silicon layer, a p-type semiconductor layer, an N-type semiconductor layer and a back contact layer to improve the mass production speed and the photoelectric conversion efficiency of the solar cell.

### BRIEF DESCRIPTION OF THE DRAWINGS

FIG. 1 is a schematic view of a thin film solar cell in accordance with a first preferred embodiment of the present invention;

FIG. 2 is a schematic view of a thin film solar cell in accordance with a second preferred embodiment of the present invention;

FIG. 3 is a schematic view of a thin film solar cell in accordance with a third preferred embodiment of the present invention; and

FIG. 4 is a flow chart of a manufacturing method of thin film solar cells in accordance with the present invention.

### DESCRIPTION OF THE PREFERRED EMBODIMENTS

The technical characteristics and effects of the present invention will become apparent by the detailed description of preferred embodiments and related drawings as follows. For simplicity, same numerals are used to represent respective elements in the preferred embodiment and drawings.

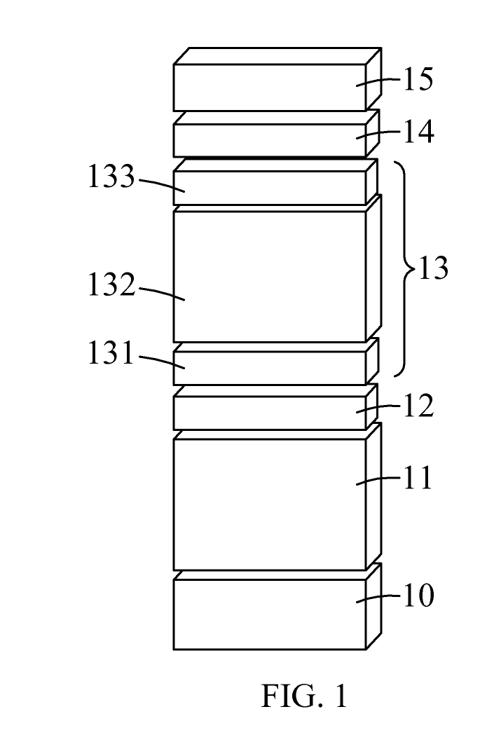

With reference to FIG. 1 for a schematic view of a thin film solar cell in accordance with the first preferred embodiment of the present invention, the thin film solar cell comprises a substrate 10, an amorphous silicon layer (a-Si layer/Cell) 11, a first conductive layer 12, a stacked I-layer 13, a second conductive layer 14 and a back contact layer 15. The substrate 10 has an illuminating surface, and the substrate 10 can be a rigid substrate or a flexible substrate. The rigid substrate can be a substrate used as a curtain glass of a building, and the flexible substrate can be a plastic substrate. The amorphous silicon layer 11 is formed above the substrate 10 and provided for absorbing photons of a shorter wavelength, and the amorphous silicon layer 11 has a higher band gap approximately equal to 1.7 eV for absorbing the photons of the higher band gap (or shorter wavelength) in a solar spectrum to improve the conversion efficiency.

The first conductive layer 12 can be a P-type semiconductor layer formed on the amorphous silicon layer 11. The P-type semiconductor refers to an intrinsic semiconductor added with impurities to produce extra holes, and the holes constitute a semiconductor with a plurality of carriers. For example, the impurity of trivalent atoms is doped into a stacked I-layer 13 to produce extra holes for silicon and germanium semiconductors. Current is operated mainly by the holes. The P-type semiconductor layer is doped by using an aluminum induced crystalline (AIC), solid phase crystalline (SPC) or excimer laser anneal (ELA) process as the main process.

The second conductive layer 14 can be an N-type semiconductor layer formed on the stacked I-layer 13. The N-type semiconductor layer refers to an intrinsic semiconductor added with impurities to produce extra electrons, and the electrons constitute a semiconductor with a plurality of carriers. For example, the impurity of pentavalent atoms is doped into a stacked I-layer 13 to produce extra electrons for silicon and germanium semiconductors. Current is operated mainly by the electrons. The N-type semiconductor layer is doped by using a thermal diffusion or an ion implantation as the main process. In addition, the back contact layer 15 formed on the second conductive layer 14 (or the N-type semiconductor layer) comprises at least one metal layer selected from the group of Al, Ag, Au, Cu, Pt and Cr and formed by a sputtering or evaporation process.

In the P-I-N structure, the stacked I-layer 13 increases the absorption range of photons of a visible spectrum and has a significant effect on the properties of the thin film solar cell. In this preferred embodiment, the stacked I-layer 13 can be an I-stacked semiconductor layer, which is a microcrystalline silicon thin film for enhancing the conversion efficiency of the solar cell, and the microcrystalline silicon thin film is formed by using a plasma enhanced chemical vapor deposition (PECVD) or a very high frequency plasma enhanced chemical vapor deposition (VHF-PECVD) process as the main process. The I-stacked semiconductor layer is made of a material including intrinsic amorphous silicon, intrinsic microcrystalline silicon, amorphous silicon doped Fluorine (F) or intrinsic microcrystalline silicon doped Fluorine (F).

In this preferred embodiment, the stacked I-layer 13 is formed on the first conductive layer 12 (or the P-type semiconductor layer). The stacked I-layer 13 is formed by stacking the three stacked I-layers 13 of different deposition rates from the bottom up, and the middle the stacked I-layer 13 has a deposition rate higher than those of the other two stacked I-layers 13. In other words, the I-stacked semiconductor layer is formed by stacking a first semiconductor I-layer 131, a second semiconductor I-layer 132 and a third semiconductor I-layer 133 of different deposition rates sequentially from the bottom up, and the second semiconductor I-layer 132 has a deposition rate higher than those of the first semiconductor I-layer 131 and the third semiconductor I-layer 133. For example, the first semiconductor I-layer 131 has a deposition rate equal to 1.6 Å/s, and the second semiconductor I-layer 132 and the third semiconductor I-layer 133 have deposition rates equal to 6.2 Å/s and 2 Å/s respectively.

In addition, the second semiconductor I-layer 132 has a crystallization rate higher than that of the third semiconductor I-layer 133, and the first semiconductor I-layer 131 has a positive orientation of the X-ray Diffraction (XRD 220/111) higher than those of the second semiconductor I-layer 132 and the third semiconductor I-layer 133 (wherein the third semiconductor I-layer 133 acts as a compensation layer). If the thickness of the second semiconductor I-layer 132 is used as a basic unit, the thickness of the first semiconductor I-layer 131 will be equal to 1/10 to 1/20 of the thickness of the second semiconductor I-layer 132, and the thickness of the third semiconductor I-layer 132 will be equal to ½ to ¼ of the thickness of the second semiconductor I-layer 132. In this preferred embodiment, the thickness of each semiconductor I-layer 131, 132 and 133 is provided for illustrating the invention only, but the actual implementation of the present invention is not limited to such arrangements only.

For example, the thickness of the first semiconductor I-layer 131 is equal to 1000 Å, and the thicknesses of the second semiconductor I-layer 132 and the third semiconductor I-layer 133 are equal to 21000 Å and 5000 Å respectively. If the thickness of the amorphous silicon layer 11 is increased from 2100 Å of the prior art to a level approximately equal to 2500 Å, and the aforementioned thickness of each of the semiconductor I-layers is used, then the photoelectric conversion efficiency of the thin film solar cell will be increased from 140 watts of the prior art to a level between 145 watts and 150 watts.

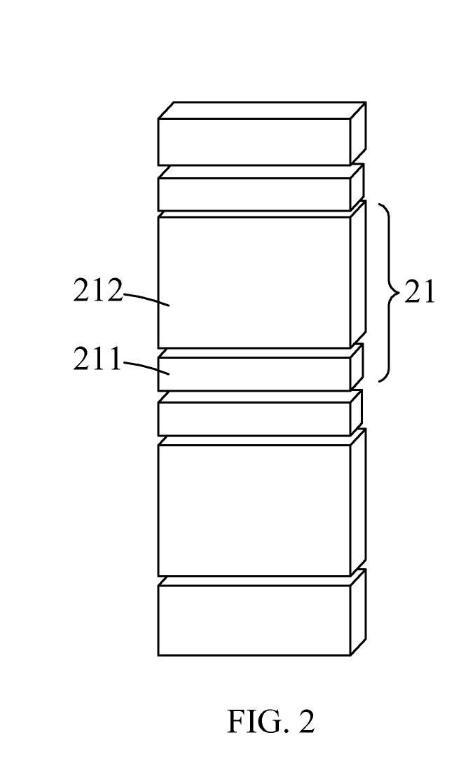

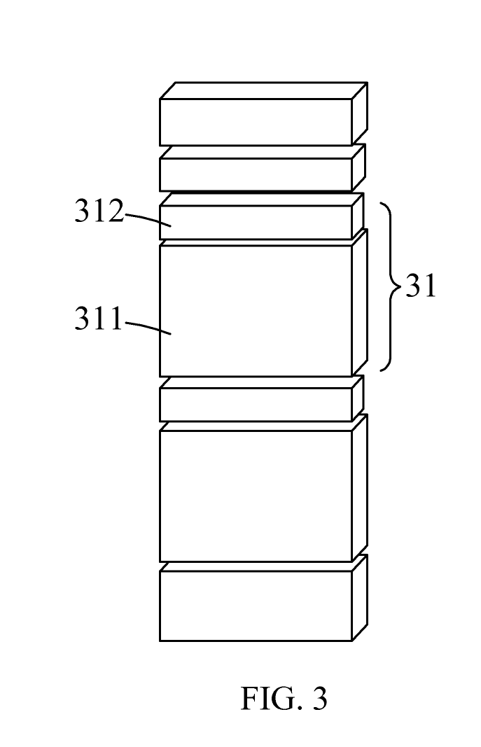

With reference to FIGS. 2 and 3 for schematic views of thin film solar cells in accordance with the second and third preferred embodiments of the present invention respectively, each of the thin film solar cells comprises a substrate, an amorphous silicon layer, a first conductive layer, a stacked I-layer, a second conductive layer and a back contact layer. These layers of the thin film solar cell are the same as described above, and thus will not be described again. However, it is noteworthy to point out that the stacked I-layer 21 of the P-I-N structure as shown in FIG. 2 is formed by stacking two stacked I-layers 21 of different deposition rates sequentially from the bottom up, and the upper layer of the two stacked I-layers 21 of different deposition rates has a deposition rate higher than that of the lower layer of the two stacked I-layers 21. In other words, the I-stacked semiconductor layer is formed by stacking a first semiconductor I-layer 211 and a second semiconductor I-layer 212 of different deposition rates sequentially from the bottom up, and the second semiconductor I-layer 212 has a deposition rate higher than that of the first semiconductor I-layer 211. For example, the first semiconductor I-layer 211 has a deposition rate equal to 1.6 Å/s, and the second semiconductor I-layer 212 has a deposition rate equal to 6.2 Å/s.

The first semiconductor I-layer 211 has a positive orientation of the X-ray diffraction (XRD 220/111) higher than that of the second semiconductor I-layer 212. If the thickness of the second semiconductor I-layer 212 is used as a basic unit, the thickness of the first semiconductor I-layer 211 can be 1/10 to 1/20 of the thickness of the second semiconductor I-layer 212.

In the stacked I-layer 31 of a P-I-N structure as shown in FIG. 3, the stacked I-layer 31 is formed by stacking a first semiconductor I-layer 311 and a second semiconductor I-layer 312 of different deposition rates from the bottom up respectively, and the first semiconductor I-layer 311 has a deposition rate higher than that of the second semiconductor I-layer 312. For example, the first semiconductor I-layer 311 has a deposition rate equal to 6.2 Å/s, and the second semiconductor I-layer 312 has a deposition rate equal to 2 Å/s.

The first semiconductor I-layer 311 has a crystallization rate higher than that of the second semiconductor I-layer 312, and the second semiconductor I-layer 312 acts as a compensation layer. If the thickness of the first semiconductor I-layer 311 is used as a basic unit, the thickness of the second semiconductor I-layer 312 can be equal to ½ to ¼ of the thickness of the first semiconductor I-layer 311. The principle and related assembly of the stacked I-layer of the present invention can be easily obtained by combining or stacking the I-layers in accordance with the description above by those ordinarily skilled in the art, and thus the principle and related assembly will not be described again.

In FIG. 2, a further description of the stacked I-layer of the present invention is given below, and the structure of a single-layer semiconductor I-layer having a deposition rate equal to 2 Å/s is compared with the structure of a double-layer stacked I-layer, wherein the first semiconductor I-layer 211 has a deposition rate of 1 Å/s, and the second semiconductor I-layer 212 has a deposition rate of 2 Å/s, and their efficiencies are 11.2% and 11.5% respectively, and their current densities are 11.5 mA/cm2 and 11.7 mA/cm2 respectively, and the open-circuit voltages of both are 1.32 volts, and the filling factors are 0.73 and 0.74 respectively. However, if the deposition rate of the second semiconductor I-layer 212 is increased to 8 Å/s, the efficiency will be increased from 10.5% to 11.3%; the current density will be increased from 11.04 mA/cm2 to 11.65 mA/cm2; the open-circuit voltages will be equal to 1.31 and 1.33 volts respectively; and the filling factors will be equal to 0.72 and 0.73 respectively. From the description above, the efficiency will be improved significantly after the deposition rate of the second semiconductor I-layer 212 is increased, if a multi-layer structure is provided.

In FIG. 3, if a structure with a single semiconductor I-layer having a deposition rate equal to 8 Å/s is compared with a structure with two stacked I-layers, and the first semiconductor I-layer 311 has a deposition rate of 8 Å/s, and the second semiconductor I-layer 312 has a deposition rate of 4 Å/s, the efficiencies will be 10.9% and 11.2% respectively; the current densities will be 11.5 mA/cm2 and 11.9 mA/cm2 respectively; the open-circuit voltages will be 1.32 and 1.33 volts respectively; and the filling factors will be 0.72 and 0.71 respectively. From the description above, the efficiency will be improved, if a multi-layer structure is provided.

In FIG. 1, if the structure including two stacked I-layers, wherein the first semiconductor I-layer 131 has a deposition rate of 1 Å/s, and the second semiconductor I-layer 132 has a deposition rate of 8 Å/s is compared with the structure including three stacked I-layers, wherein the first semiconductor I-layer 131 has a deposition rate of 1 Å/s, and the second semiconductor I-layer 132 and the third semiconductor I-layer 133 have deposition rates equal to 8 Å/s and 4 Å/s respectively, the efficiencies will be 11.3% and 11.9% respectively; the current densities will be 11.65 mA/cm2 and 12.3 mA/cm2 respectively; the open-circuit voltages of both will be 1.33 volts; and the filling factors of both will be 0.73. However, if the deposition rate of the second semiconductor I-layer 132 is increased to 14 Å/s, the efficiency will be increased from 9.7% to 11%; the current density will be increased from 10.7 mA/cm2 to 11.7 mA/cm2; the open-circuit voltages will be 1.3 volts and 1.32 volts respectively; and the filling factors will be 0.69 and 0.72 respectively. From the description above, the efficiency will be improved significantly after the deposition rate of the second semiconductor I-layer 132 is increased, if a multi-layer structure is provided.

It is noteworthy to mention that the implementation of the thin film solar cells in accordance with the present invention can also comprise a substrate, a first amorphous silicon layer, a second amorphous silicon layer, a first conductive layer, a stacked I-layer, a second conductive layer and a back contact layer, or comprise a substrate, an amorphous silicon layer, a first conductive layer, a first stacked I-layer, a second stacked I-layer, a second conductive layer and a back contact layer. In other words, the thin film solar cell of the present invention can comprise two continuously stacked amorphous silicon layers or two continuously stacked I-layers. The stacked I-layers can be those described in the aforementioned embodiments, so that the photoelectric conversion efficiency of the thin film solar cell can be improved to a level over 150 watts.

In the foregoing process of describing the thin film solar cell of the present invention, the concept of the manufacturing method of thin film solar cells of the present invention has been described, but a flow chart is further provided for illustrating the manufacturing method in details as follows.

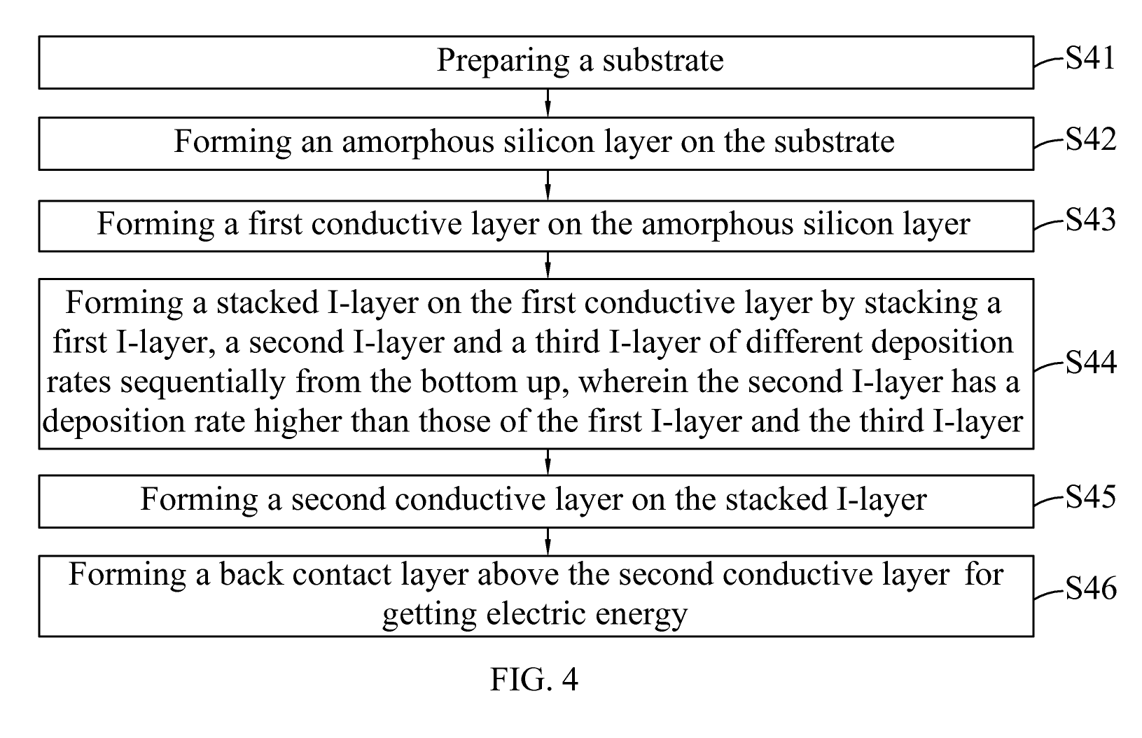

With reference to FIG. 4 for a flow chart of a manufacturing method of thin film solar cells in accordance with the present invention, the manufacturing method of thin film solar cells of the present invention is applicable for a thin film solar cell, and the thin film solar cell comprises a substrate, an amorphous silicon layer, a first conductive layer, a stacked I-layer, a second conductive layer and a back contact layer. The manufacturing method comprises the steps of:

(S41) preparing a substrate;

(S42) forming an amorphous silicon layer on the substrate;

(S43) forming a first conductive layer on the amorphous silicon layer;

(S44) forming a stacked I-layer on the first conductive layer by stacking a first I-layer, a second I-layer and a third I-layer of different deposition rates sequentially from the bottom up, wherein the second I-layer has a deposition rate higher than those of the first I-layer and the third I-layer;

(S45) forming a second conductive layer on the stacked I-layer; and

(S46) forming a back contact layer above the second conductive layer for getting electric energy.

Further, the other two manufacturing methods of thin film solar cells are similar to that described above. In addition, the detailed description and implementation of the manufacturing method of thin film solar cells of the present invention have been provided in the aforementioned description of the thin film solar cell of the present invention, and thus will not be described again.

In summation of the description above, the manufacturing method of thin film solar cells provides a thin film solar cell having different I-layers, substrates, amorphous silicon layers, p-type semiconductor layers, N-type semiconductor layers and back contact layers to enhance the photoelectric conversion efficiency of the solar cell.

While the invention has been described by means of specific embodiments, numerous modifications and variations could be made thereto by those skilled in the art without departing from the scope and spirit of the invention set forth in the claims.

What is claimed is:

1. A thin film solar cell, comprising:
a substrate;
an amorphous silicon layer, disposed on the substrate;
a first conductive layer, disposed on the amorphous silicon layer;
a stacked I-layer, disposed on the first conductive layer, and formed by stacking a first I-layer, a second I-layer and a third I-layer of different deposition rates sequentially from the bottom up, and the second I-layer having a deposition rate higher than deposition rates of the first I-layer and the third I-layer;
a second conductive layer, disposed on the stacked I-layer; and
a back contact layer, disposed above the second conductive layer, for getting electric energy.

2. The thin film solar cell of claim 1, wherein the second I-layer has a higher crystallization rate than the crystallization rate of the third I-layer.

3. The thin film solar cell of claim 1, wherein the first I-layer has a thickness equal to 1/10 to 1/20 of the thickness of the second I-layer, and the third I-layer has a thickness equal to ½ to ¼ of the thickness of the second I-layer.

4. The thin film solar cell of claim 1, wherein the first I-layer is formed at a deposition rate ranging from 1 Å/s to 3 Å/s, and the second I-layer is formed at a deposition rate ranging from 3 Å/s to 15 Å/s.

5. The thin film solar cell of claim 1, wherein the first I-layer is a positive orientation semiconductor I-layer.

6. A manufacturing method of thin film solar cells, comprising the steps of:
preparing a substrate;
forming an amorphous silicon layer on the substrate;
forming a first conductive layer on the amorphous silicon layer;
forming a stacked I-layer on the first conductive layer by stacking a first I-layer, a second I-layer and a third I-layer of different deposition rates sequentially from the bottom up, and the second I-layer having a deposition rate higher than deposition rates of the first I-layer and the third I-layer;
forming a second conductive layer on the stacked I-layer; and
forming a back contact layer above the second conductive layer for getting electric energy.

7. The manufacturing method of thin film solar cells of claim 6, wherein the second I-layer has a higher crystallization rate than the crystallization rate of the third I-layer.

8. The manufacturing method of thin film solar cells of claim 6, wherein the first I-layer has a thickness equal to 1/10˜ 1/20 of the thickness of the second I-layer, and the third I-layer has a thickness equal to ½˜¼ of the thickness of the second I-layer.

9. The manufacturing method of thin film solar cells of claim 6, wherein the first I-layer has a deposition rate ranging from 1 Å/s to 3 Å/s.

10. The manufacturing method of thin film solar cells of claim 6, wherein the second I-layer has a deposition rate ranging from 3 Å/s to 15 Å/s.

11. The manufacturing method of thin film solar cells of claim 6, wherein the first I-layer is a positive orientation semiconductor I-layer.

12. A thin film solar cell, comprising:
a substrate;
an amorphous silicon layer, disposed on the substrate;
a first conductive layer, disposed on the amorphous silicon layer;
a stacked I-layer, disposed on the first conductive layer, and formed by stacking a first I-layer and a second I-layer of different deposition rates sequentially from the bottom up, and the second I-layer having a deposition rate higher than a deposition rate of the first I-layer;
a second conductive layer, disposed on the stacked I-layer; and
a back contact layer, disposed above the second conductive layer, for getting electric energy.

13. The thin film solar cell of claim 12, wherein the first I-layer has a thickness equal to 1/10˜ 1/20 of the thickness of the second I-layer.

14. The thin film solar cell of claim 12, wherein the first I-layer is formed at a deposition rate ranging from 1 Å/s to 3 Å/s, and the second I-layer is formed at a deposition rate ranging from 3 Å/s to 15 Å/s.

15. The thin film solar cell of claim 12, wherein the first I-layer is a positive orientation semiconductor I-layer.

16. A manufacturing method of thin film solar cells, comprising the steps of:
preparing a substrate;
forming an amorphous silicon layer on the substrate;
forming a first conductive layer on the amorphous silicon layer;
forming a stacked I-layer on the first conductive layer by stacking a first I-layer and a second I-layer of different deposition rates sequentially from the bottom up, and the second I-layer having a deposition rate higher than a deposition rate of the first I-layer;
forming a second conductive layer on the stacked I-layer; and
forming a back contact layer above the second conductive layer, for getting electric energy.

17. The manufacturing method of thin film solar cells of claim 16, wherein the first I-layer has a thickness equal to 1/10˜ 1/20 of the thickness of the second I-layer.

18. The manufacturing method of thin film solar cells of claim 16, wherein the first I-layer has a deposition rate ranging from 1 Å/s to 3 Å/s.

19. The manufacturing method of thin film solar cells of claim 16, wherein the second I-layer has a deposition rate ranging from 3 Å/s to 15 Å/s.

20. The manufacturing method of thin film solar cells of claim 16, wherein the first I-layer is a positive orientation semiconductor I-layer.

21. A thin film solar cell, comprising:
a substrate;
an amorphous silicon layer, disposed on the substrate;
a first conductive layer, disposed on the amorphous silicon layer;
a stacked I-layer, disposed on the first conductive layer, and formed by stacking a first I-layer and a second I-layer of different deposition rates sequentially from the bottom up, and the first I-layer having a deposition rate higher than a deposition rate of the second I-layer;
a second conductive layer, disposed on the stacked I-layer; and
a back contact layer, disposed above the second conductive layer for getting electric energy.

22. The thin film solar cell of claim 21, wherein the first I-layer has a higher crystallization rate than the crystallization rate of the second I-layer.

23. The thin film solar cell of claim 21, wherein the second I-layer has a thickness equal to ½˜¼ of the thickness of the first I-layer.

24. The thin film solar cell of claim 21, wherein the first I-layer is formed at a deposition rate ranging from 3 Å/s to 15 Å/s, and the second I-layer is formed at a deposition rate ranging from 3 Å/s to 10 Å/s.

25. The thin film solar cell of claim 21, wherein the second I-layer is a compensation layer.

26. A manufacturing method of thin film solar cells, comprising the steps of:
preparing a substrate;
forming an amorphous silicon layer on the substrate;
forming a first conductive layer on the amorphous silicon layer;
forming a stacked I-layer on the first conductive layer by stacking a first I-layer and a second I-layer of different deposition rates sequentially from the bottom up, and the first I-layer having a deposition rate higher than a deposition rate of the second I-layer;
forming a second conductive layer on the stacked I-layer; and
forming a back contact layer above the second conductive layer, for getting electric energy.

27. The manufacturing method of thin film solar cells of claim 26, wherein the first I-layer has a higher crystallization rate than the crystallization rate of the second I-layer.

28. The manufacturing method of thin film solar cells of claim 26, wherein the second I-layer has a thickness equal to ½ to ¼ of the thickness of the first I-layer.

29. The manufacturing method of thin film solar cells of claim 26, wherein the first I-layer has a deposition rate ranging from 3 Å/s to 15 Å/s.

30. The manufacturing method of thin film solar cells of claim 26, wherein the second I-layer has a deposition rate ranging from 3 Å/s to 10 Å/s.

31. The manufacturing method of thin film solar cells of claim 26, wherein the second I-layer is a compensation layer.
